(19) United States
(12) Patent Application Publication
(10) Pub. No.: US 2008/0284047 A1
(43) Pub. Date: Nov. 20, 2008

(54) Chip Package with Stiffener Ring

(76) Inventors: Eric Tosaya, Fremont, CA (US); Jun Zhai, San Jose, CA (US); Chia-Ken Leong, Santa Clara, CA (US); Tom Ley, Cupertino, CA (US)

Correspondence Address: TIMOTHY M HONEYCUTT ATTORNEY AT LAW, P O BOX 1577, CYPRESS, TX, 77410, US

(21) Appl. No.: 11/748,618

(22) Filed: May 15, 2007

(51) Int. Cl. H01L 23/28; H01L 21/00

(52) U.S. Cl. 257/787; 438/127; 257/E23.116

(57) ABSTRACT

Various semiconductor chip packages and methods of making the same are provided. In one aspect, a method of manufacturing is provided that includes providing a substrate that has a first side and a first plurality of passive devices in the first side. A polymeric stiffener ring is formed on the first side. The stiffener ring embeds the first plurality of passive devices without covering a central portion of the first surface of the substrate. A semiconductor chip is mounted on the central portion of the first surface of the substrate.

### BACKGROUND OF THE INVENTION

1. Field of the Invention

This invention relates generally to semiconductor processing, and more particularly to semiconductor chip packaging and to methods of making the same.

2. Description of the Related Art

Many current integrated circuits are formed as multiple die on a common silicon wafer. After the basic process steps to form the circuits on the die are complete, the individual die are cut from the wafer. The cut die are then usually mounted to structures, such as circuit boards, or packaged in some form of enclosure.

One frequently-used package consists of a substrate upon which a die is mounted. The upper surface of the substrate includes electrical interconnects. The die is manufactured with a plurality of bond pads. A collection of solder bumps are provided between the bond pads of the die and substrate interconnects to establish ohmic contact. An underfill material is deposited between the die and the substrate to act as a material that prevents damage to the solder bumps due to mismatches in the coefficients of thermal expansion between the die and the substrate, and an adhesive to hold the die. The substrate interconnects include an array of solder pads that are arranged to line up with the die solder bumps. After the die is seated on the substrate, a reflow process is performed to enable the solder bumps of the die to metallurgically link to the solder pads of the substrate. After the die is mounted to the substrate, a lid is attached to the substrate to cover the die. Some conventional integrated circuits, such as microprocessors, generate sizeable quantities of heat that must be ferried away to avoid device shutdown or damage. For these devices, the lid serves as both a protective cover and a heat transfer pathway.

One conventional type of substrate consists of a core laminated between upper and lower build-up layers. The core itself usually consists of four layers of glass filled epoxy. The build-up layers, which may number four or more on opposite sides of the core, are formed from some type of resin. Various metallization structures are interspersed in the core and build-up layers in order to provide electrical pathways between pins or pads on the lowermost layer of the substrate and pads the solder pits that bond with the chip solder bumps.

The core provides a certain stiffness to the substrate. Even with that provided stiffness, conventional substrates still tend to warp due to mismatches in coefficients of thermal expansion for the chip, underfill and substrate. However, there is a need to provide shorter electrical pathways in package substrates in order to lower power supply inductance and improve power fidelity for power transferred through the substrate. The difficult problem is how to reduce the electrical pathways without inducing potentially damaging substrate warping.

The present invention is directed to overcoming or reducing the effects of one or more of the foregoing disadvantages.

### SUMMARY OF THE INVENTION

In accordance with one aspect of the present invention, a method of manufacturing is provided that includes providing a substrate that has a first side and a first plurality of passive devices in the first side. A polymeric stiffener ring is formed on the first side. The stiffener ring embeds the first plurality of passive devices without covering a central portion of the first surface of the substrate. A semiconductor chip is mounted on the central portion of the first surface of the substrate.

In accordance with another aspect of the present invention, a method of manufacturing is provided that includes providing a substrate that has a first side and a first plurality of passive devices in the first side. A polymeric stiffener ring is formed on the first side. The stiffener ring embeds the first plurality of passive devices without covering a central portion of the first surface of the substrate. A semiconductor chip is mounted on the central portion of the first surface of the substrate. A lid is coupled to the stiffener ring to cover the semiconductor chip.

In accordance with another aspect of the present invention, a method of manufacturing is provided that includes providing a substrate that has a first side. A polymeric stiffener ring is molded directly on the first side. The stiffener ring does not covering a central portion of the first surface of the substrate. A semiconductor chip is mounted on the central portion of the first surface of the substrate.

In accordance with another aspect of the present invention, a method of manufacturing is provided that includes providing a sheet of substrate material and molding polymeric stiffener rings on selected portions of the sheet of substrate material. The selected portions of the sheet of substrate material are separated into individual substrates each having a stiffener ring.

In accordance with another aspect of the present invention, an apparatus is provided that includes a substrate that has a first side and a first plurality of passive devices in the first side. A polymeric stiffener ring is on the first side. The stiffener ring embeds the first plurality of passive devices without covering a central portion of the first surface of the substrate. A semiconductor chip is mounted on the central portion of the first surface of the substrate.

### BRIEF DESCRIPTION OF THE DRAWINGS

The foregoing and other advantages of the invention will become apparent upon reading the following detailed description and upon reference to the drawings in which:

FIG. 1 is a pictorial view of an exemplary embodiment of an integrated circuit package;

FIG. 2 is a pictorial view like FIG. 1, but with an exemplary lid exploded from the package substrate;

FIG. 3 is a sectional view of FIG. 1 taken at section 3-3;

FIG. 4 is a magnified view of a portion of FIG. 3;

FIG. 5 is a view like FIG. 4, but of an alternate exemplary package;

FIG. 6 is a view like FIG. 5, but of another alternate exemplary package;

FIG. 7 is a sectional view of an exemplary substrate positioned in an exemplary mold for molding a stiffener ring to the substrate;

FIG. 8 is a sectional view of the substrate following mold removal;

FIG. 9 is a sectional of an alternate exemplary package substrate; and

FIG. 10 is a pictorial view of an alternate exemplary mold suitable for molding multiple stiffener mold rings.

### DETAILED DESCRIPTION OF SPECIFIC EMBODIMENTS

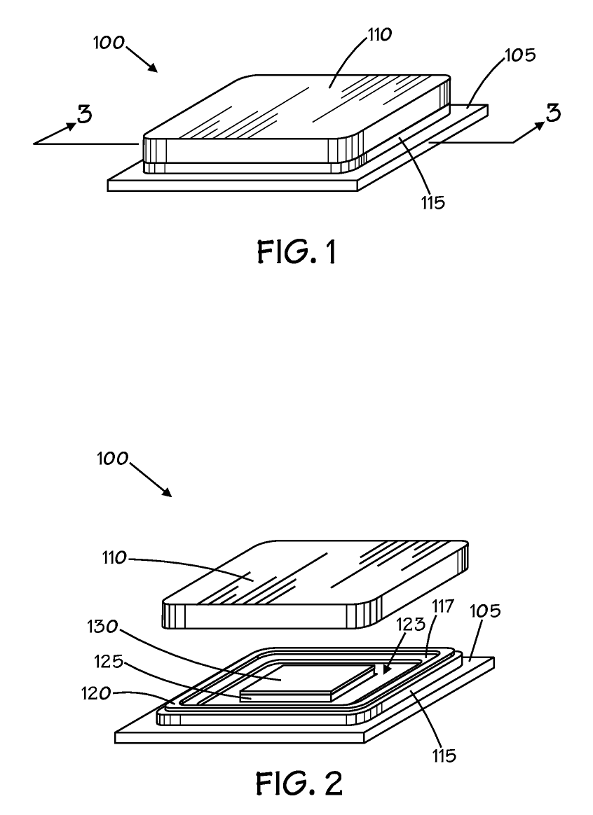

In the drawings described below, reference numerals are generally repeated where identical elements appear in more than one figure. Turning now to the drawings, and in particular to FIG. 1, therein is shown a pictorial view of an exemplary embodiment of an integrated circuit package 100 that includes a substrate 105, an overlying lid 110 and a stiffener ring 115. The stiffener ring 115 is sandwiched between the substrate 105 and the lid 110. The substrate 105 is advantageously a land grid array (“LGA”) but may optionally be a pin grid array, a ball grid array or other type of mountable substrate as desired. The lid 110 covers an integrated circuit (not visible) that is mounted on the substrate 105. Optionally, the package 100 may be lidless, partially or completely overmolded, or glob topped.

Additional detail regarding the structure of the package 100 may be understood by referring now also to FIG. 2, which is a pictorial view like FIG. 1 but with the lid 110 exploded from the substrate 105. An upper surface 117 as well as the remainder of the stiffener ring 115 is revealed and has a footprint that generally tracts the outline of the overlying lid 110. An adhesive bead 120 is disposed on the upper surface 117 of the stiffener ring 115 and used to secure the lid 110 thereto. The stiffener ring is a frame-like structure that does not cover a central portion 123 of the substrate 105. It should be understood that the stiffener ring 115 may extend laterally to the edges of the substrate 105 if desired.

An integrated circuit 125, which may be a semiconductor chip or other type of device as desired, is mounted on the central portion of the substrate 105. The integrated circuit 125 may be any of a myriad of different types of circuit devices used in electronics, such as, for example, microprocessors, graphics processors, application specific integrated circuits, memory devices or the like, and may be single or multi-core. Optionally, multiple chips may be used. The integrated circuit 125 includes a thermal interface material 130 that is designed to provide an advantageous conductive heat transfer pathway between the integrated circuit 125 and the overlying lid 110.

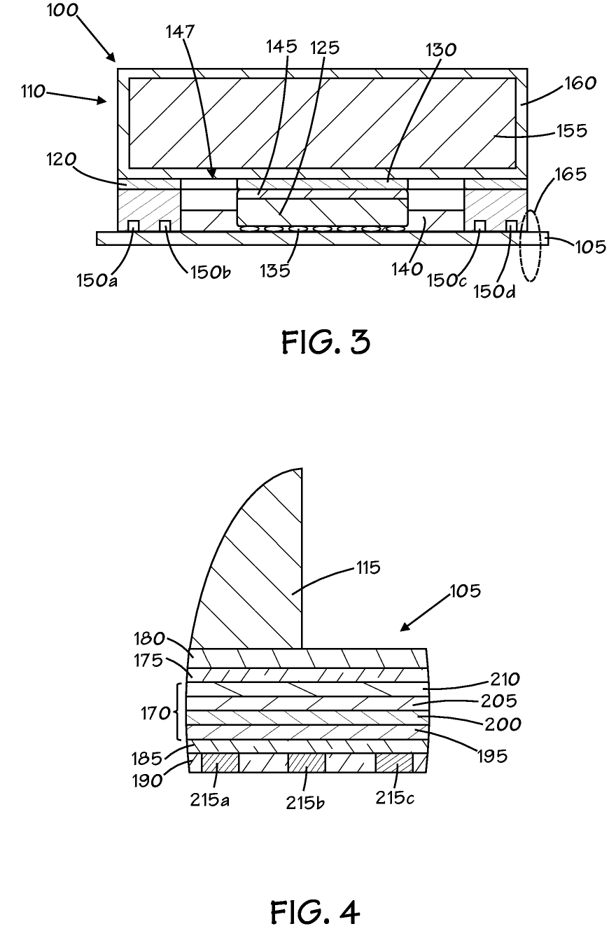

Still further detail regarding the package 100 may be understood by referring now to FIG. 3, which is a sectional view of FIG. 1 taken at section 3-3. The integrated circuit 125 is mounted in flip-chip fashion and connected electrically to the substrate 105 by plurality of solder bumps 135. An underfill material 140 is positioned between the integrated circuit 125 and the substrate to address issues of differing coefficients of thermal expansion for the substrate 105 and the integrated circuit 125. A backside metallization layer or stack 145 may be provided on the upper surface of the integrated circuit 125 to provide one or more layers that facilitate metallurgical bonding with the thermal interface material 130. The materials suitable for the stack 145 will depend on the type of thermal interface material 130. The thermal interface material 130 is designed to bond with the lower surface 147 of the lid 110 and provide an effective conductive heat transfer pathway between the integrated circuit 125 and the lid 110. The thermal interface material 130 is advantageously composed of metallic materials, such as indium, but may also be composed of polymeric materials such as, for example, silicone rubber mixed with aluminum particles and zinc oxide. Optionally, compliant base materials other than silicone rubber and thermally conductive particles other than aluminum may be used.

The lid 110 may be composed of well-known plastics, ceramics or metallic materials as desired. Some exemplary materials include nickel plated copper, anodized aluminum, aluminum-silicon-carbide, aluminum nitride, boron nitride or the like. In an exemplary embodiment, the lid 110 may consist of a copper core 155 surrounded by a nickel jacket 160. As noted above in conjunction with FIG. 2, the lid 110 is secured to the stiffener ring 115 by way of an adhesive bead 120.

One or more passive devices, such as capacitors, inductors, resistors or the like, or other types of circuit elements may be provided for the integrated circuit 125. In this regard, four passive elements, such as capacitors, are shown and labeled 150a, 150b, 150c and 150d. The passive elements 150a, 150b, 150c and 150d are of such small size in FIG. 3 that they are not depicted with cross-hatching. The passive devices 150a, 150b, 150c and 150d are advantageously embedded within the stiffener ring 115. Electrical interconnects between the passive devices 150a, 150b, 150c and 150d and the integrated circuit 125 are not visible. The portion of FIG. 3 circumscribed by the dashed oval 165 will be used to describe additional details of the package 100 in conjunction with FIG. 4.

Attention is now turned to FIG. 4, which is a magnified view of the portion of FIG. 3 circumscribed by the dashed oval 165. Again it should be remembered that only a small portion of the stiffener ring 115 and the substrate 105 are visible in FIG. 4. The substrate 105 may consist of a core/build-up configuration. In this regard, the substrate 105 may consist of a central core 170 upon which two build-up layers 175 and 180 are formed and below which two additional build-up layers 185 and 190 are formed. The core itself 170 may consist of a stack of four layers 195, 200, 205 and 210. This arrangement may be termed a so called “2-4-2” arrangement that refers to a four-layer core laminated between two sets of two build-up layers. The number of layers in the substrate 105 can vary from four to sixteen or more, although less than four may be used. Since the substrate 105 is depicted as a LGA configuration, the lowermost build-up layer 190 may be provided with a plurality of bond pads 215a, 215b and 215c that are designed to make ohmic contact with some form of conductor on a printed circuit board or other type of device. Of course, if the substrate 105 were configured as a pin grid array then downwardly projecting conductor pins would be depicted. The various layers of the core 170 and the build-up layers 175, 180, 185 and 190 will typically include metallization layers, vias, interconnects, etc. to establish conducting pathways between the bond pads 215a, 215b and 215c and the corresponding bond pads (not shown) that are electrically connected to the solder bumps 135 depicted in FIG. 3. The stiffener ring 115 is designed to provide, as its name implies, a stiffening for the substrate 105. This provision for an enhanced stiffening of the substrate 105 may be particularly advantageous in situations where a substrate is configured as a so-called thin core or coreless.

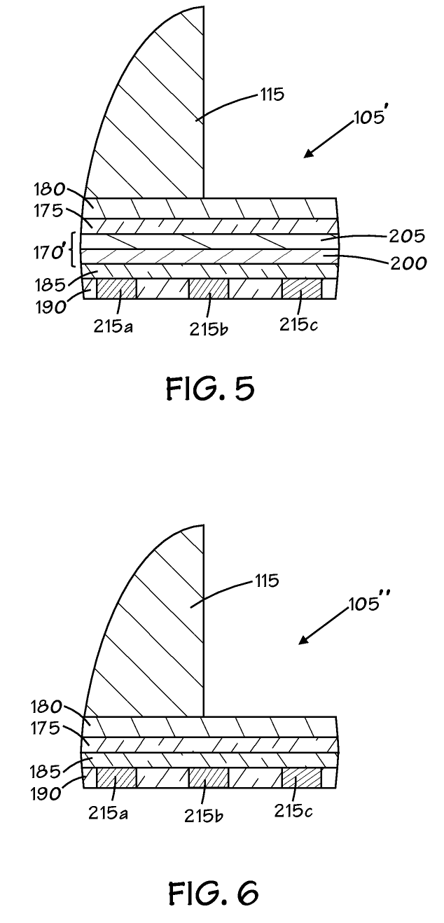

An exemplary embodiment of a thin core substrate 105′ is depicted in FIG. 5, which is a view like FIG. 4, but of the thin core substrate 105′. Here, the substrate 105′ consists of a core 170′ and two overlying build-up layers 175 and 180 and two underlying build-up layers 185 and 190. However, the core 170′ consists of just two layers 200 and 205. In this circumstance, the core 170′ and the overall substrate 105′ will generally have a lower native stiffness than a substrate with a larger core. In this circumstance, the provision of the stiffener ring 115 will greatly enhance the overall stiffness of the substrate and thus the planarity and resistance to warpage thereof. Like the other embodiment depicted in FIG. 4, the lowermost build-up layer 190 may be provided with a plurality of bond pads 215a, 215b and 215c.

As noted briefly above, the stiffener ring 115 maybe employed on a substrate that is coreless. Such an alternate embodiment is depicted in FIG. 6, which is a sectional view like FIG. 5, but of a substrate 105″ that is coreless. The substrate 105″ is coreless in the sense that a core is not laminated between build-up layers. In this embodiment, the substrate 105″ may consist of two build-up layers 175 and 180 stacked on two other build-up layers 185 and 190. Again the lowermost build-up layer 190 may include a plurality of bond pads 215a, 215b and 215c.

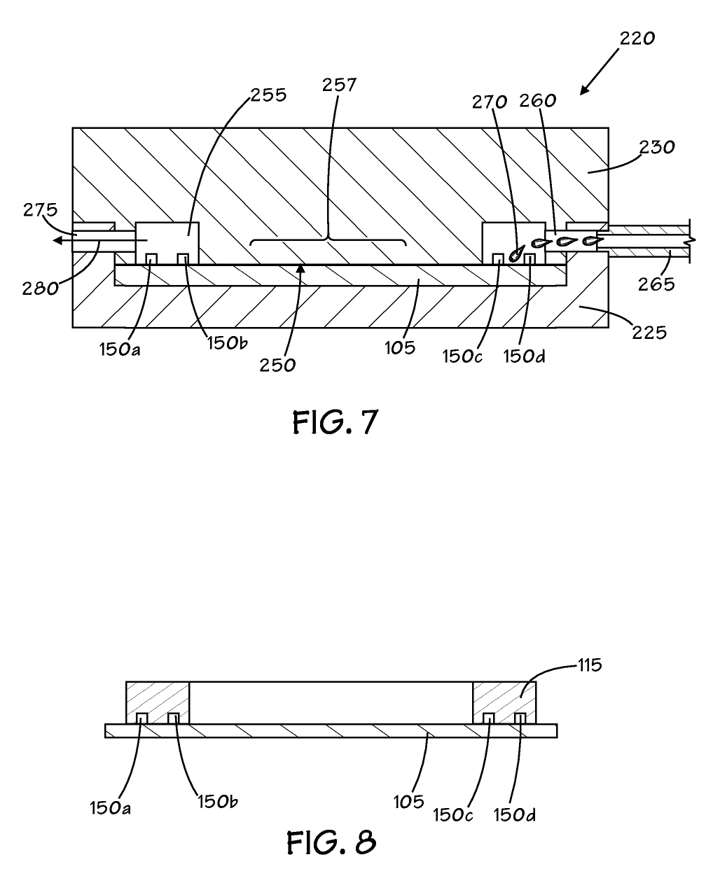

It is envisioned that the stiffener ring 115 may be advantageously formed by a molding process. The exact configuration of a suitable mold to fabricate the stiffener ring 115 is subject to great variation. One exemplary embodiment of a mold 220 may be understood by referring now to FIG. 7, which is a sectional view showing an exemplary substrate 105 positioned inside the mold 220. In this embodiment, the mold 220 may consist of a lower half 225 and a mating upper half 230. The lower half 225 may have a generally bathtub shape as shown so that the substrate 105 may be placed therein and the top half 230 may then be brought down onto the bottom half 225. The upper half 230 is provided with an interior space 255 that has the desired shape of the stiffener ring to be molded. If there are structures on the upper surface 250 of the substrate 105 that may be damaged by physical contact, the upper half 230 may be provided with an interior space in the vicinity labeled 257.

A fluid passage 260 is provided that is in fluid communication with the interior space 255. A fluid supply line 265 may be coupled to the passage 260 and used to introduce the molding fluid 270 into the interior space 255 as shown. In order to exhaust air that might otherwise be trapped within the interior space 255 during the injection of the fluid 270, an air vent 275 may be provided in the upper half 230 and in fluid communication with the interior space 255 to allow air 280 to be expelled therefrom.

As the liquid 270 is introduced into the interior space 255, the passive devices 150a, 150b, 150c and 150d positioned on the substrate 105 will be embedded within the liquid 270 and ultimately the stiffener ring 115 when the liquid is cured. Suitable candidates for the liquid 270 include polymeric materials that may be molded, directly to the substrate without an adhesive if desired, and that exhibit desired coefficients of thermal expansion and bulk modulus. The ability of the stiffener ring 115 to resist substrate warping will be greater where the liquid 270 hardens into a stiffener ring 115 that has a coefficient of thermal expansion and a bulk modulus that approach or even equal that of the substrate 105. Various epoxy resins represent suitable materials. In one example, a 2-4-2 substrate with a coefficient of thermal expansion of about 22×10⁻⁶ C°⁻¹ and a bulk modulus of about 25 to 30 GPa may be matched with an epoxy resin available from Matsushita that has a coefficient of thermal expansion of about 14×10⁻⁶ C°⁻¹ and a bulk modulus of about 20 to 25 GPa. Thin core or coreless substrates may have coefficients of thermal expansion of between about 15×10⁻⁶ C°⁻¹ to 19×10⁻⁶ C°⁻¹. Accordingly, resins with coefficients of thermal expansion in that range may be suitable for thin or coreless substrates.

Many moldable epoxy materials begin to cure upon heating up to a certain temperature. In one example, a pellet of resin is melted into a liquid state by heating to about 175° C. for up to about 120 seconds. The liquid is then delivered to the mold 220 and allowed to set.

After the liquid 270 solidifies into the stiffener ring 115, the mold 220 may be opened and the substrate 105 removed therefrom as depicted in FIG. 8, which again is a sectional view. Any flashing on the stiffener ring 115 left over after the molding process may be removed using well-known cutting or other material removal techniques. A final thermal cure of the ring 115 may be performed if necessary. Note that the stiffener ring 115 is now in position and embeds the passive devices 150a, 150b, 150c and 150d. The process is simpler than a conventional stiffener ring process since the stiffener ring 115 is molded directly to the substrate without the need for a separate adhesive. At this point, the integrated circuit 125 depicted in FIG. 3 may be mounted to the substrate and additional circuit elements such as passive devices may be mounted to the substrate 105 inside of the opening provided by the stiffener ring 115 as desired. Thereafter, the lid 110 depicted in FIGS. 1, 2 and 3 may be secured to the stiffener ring 115 by way of the adhesive 120 as depicted in FIGS. 2 and 3 and described elsewhere herein.

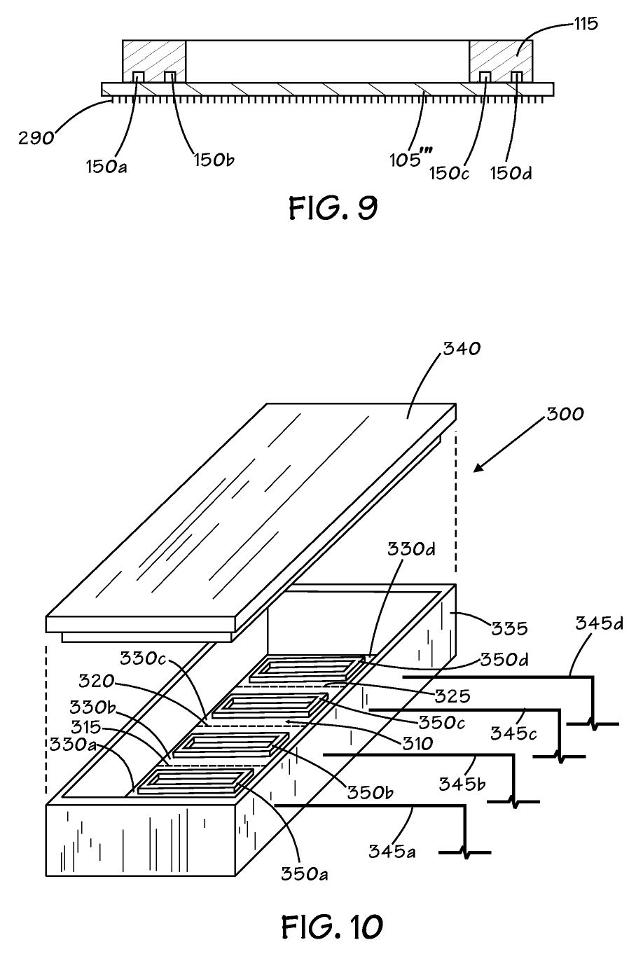

As noted above, something other than a LGA design may be used. FIG. 9 is a sectional view of an alternate embodiment of a substrate 105′″ that is configured as a pin grid array. A plurality of conductor pins 290 are coupled to the substrate 105′″. Metallization layers (not visible) in the substrate 105′″ provide electrical pathways between the pins 290 and a chip that may be mounted, such as the chip 125 shown in FIGS. 2 and 3. The substrate 105′″ may be conventional core, thin core or coreless.

Manufacturing efficiency may be achieved if multiple substrates can be provided with stiffener rings in a single molding process. In this regard, FIG. 10 depicts a pictorial view of a multi-chip mold 300 in which a substrate sheet 310 is positioned. The substrate sheet 310 may be cut at the dashed lines 315, 320 and 325, by for example, sawing, to yield four substrates 330a, 330b, 330c and 330d. The mold 300 includes a lower half 335 in which the substrate sheet 310 is seated and an upper half 340 that is shown exploded from the lower half 335. Resin supply lines 345a, 345b, 345c and 345d may be connected to the upper half 340 to supply resin for the molding process. The upper half 340 may be configured like a group of the mold upper halves 230 (see FIG. 7) connected together or as some other design. When the upper and lower halves 335 and 340 are brought together, a molding process may be performed to yield stiffener rings 350a, 350b, 350c and 350d on the substrates 330a, 330b, 330c and 330d respectively. Of course, the sheet 310 and mold 300 may be configured for more or less than four substrates.

While the invention may be susceptible to various modifications and alternative forms, specific embodiments have been shown by way of example in the drawings and have been described in detail herein. However, it should be understood that the invention is not intended to be limited to the particular forms disclosed. Rather, the invention is to cover all modifications, equivalents and alternatives falling within the spirit and scope of the invention as defined by the following appended claims.

What is claimed is:

1. A method of manufacturing, comprising:
providing a substrate having a first side and a first plurality of passive devices on the first side;
forming a polymeric stiffener ring on the first side, the stiffener ring embedding the first plurality of passive devices while not covering a central portion of the first surface of the substrate; and
mounting a semiconductor chip on the central portion of the first surface of the substrate.

2. The method of claim 1, wherein the forming of the stiffener ring comprises molding a polymeric resin.

3. The method of claim 1, comprising coupling a second plurality of passive devices to the central portion of the first surface of the substrate between the semiconductor chip and the stiffener ring.

4. The method of claim 5, comprising forming a underfill layer under the semiconductor chip and over the second plurality of passive devices.

5. The method of claim 1, comprising coupling a plurality of bond pads to a second side of the substrate.

6. The method of claim 1, comprising coupling a plurality of conductor pins to the second side of the substrate.

7. The method of claim 1, wherein the forming of the polymeric stiffener ring comprises forming a rectangular polymeric stiffener ring.

8. The method of claim 1, wherein the providing of the substrate comprises providing a coreless substrate.

9. A method of manufacturing, comprising:
providing a substrate having a first side and a first plurality of passive devices on the first side;
forming a polymeric stiffener ring on the first side, the stiffener ring embedding the first plurality of passive devices while not covering a central portion of the first surface of the substrate;
mounting a semiconductor chip on the central portion of the first surface of the substrate; and
coupling a lid to the stiffener ring to cover the semiconductor chip.

10. The method of claim 9, wherein the forming of the stiffener ring comprises molding a polymeric resin.

11. The method of claim 9, comprising coupling a second plurality of passive devices to the central portion of the first surface of the substrate between the semiconductor chip and the stiffener ring.

12. The method of claim 11, comprising forming a underfill layer under the semiconductor chip and over the second plurality of passive devices.

13. The method of claim 9, comprising coupling a plurality of bond pads to a second side of the substrate.

14. The method of claim 9, comprising coupling a plurality of conductor pins to the second side of the substrate.

15. The method of claim 9, wherein the forming of the polymeric stiffener ring comprises forming a rectangular polymeric stiffener ring.

16. The method of claim 9, wherein the providing of the substrate comprises providing a coreless substrate.

17. A method of manufacturing, comprising:
providing a substrate having a first side;
molding a polymeric stiffener ring directly on the first side, the stiffener ring not covering a central portion of the first surface of the substrate; and
mounting a semiconductor chip on the central portion of the first surface of the substrate.

18. The method of claim 17, wherein the molding of the stiffener ring comprises molding a polymeric resin.

19. The method of claim 17, wherein the providing of the substrate comprises providing a substrate having a plurality of passive devices on the first side thereof, the molding of the stiffener embedding the plurality of passive devices.

20. The method of claim 17, comprising forming a underfill layer under the semiconductor chip.

21. The method of claim 17, comprising coupling a plurality of bond pads to a second side of the substrate.

22. The method of claim 17, comprising coupling a plurality of conductor pins to the second side of the substrate.

23. The method of claim 17, wherein the forming of the polymeric stiffener ring comprises forming a rectangular polymeric stiffener ring.

24. The method of claim 17, wherein the providing of the substrate comprises providing a coreless substrate.

25. A method of manufacturing, comprising:
providing a sheet of substrate material;
molding polymeric stiffener rings on selected portions of the sheet of substrate material; and
separating the selected portions of the sheet of substrate material into individual substrates each having a stiffener ring.

26. The method of claim 25, wherein the molding of the polymeric stiffener rings comprises molding a polymeric resin.

27. The method of claim 25, wherein the providing of the sheet of substrate material comprises providing a sheet wherein each of the selected portions thereof have a corresponding plurality of passive devices, the molding of the stiffener rings embedding the corresponding pluralities of passive devices.

28. The method of claim 25, comprising mounting a semiconductor chip on each of the individual substrates.

29. The method of claim 25, comprising coupling pluralities of bond pads to sides of the substrates opposite their respective stiffener rings.

30. The method of claim 25, comprising coupling a plurality of conductor pins to sides of the substrates opposite their respective stiffener rings.

31. The method of claim 25, wherein the molding of the polymeric stiffener ring comprises forming a rectangular polymeric stiffener rings.

32. The method of claim 25, wherein the providing of the sheet of substrate material comprises providing a coreless sheet of substrate material.

33. An apparatus, comprising:
a substrate having a first side and a first plurality of passive devices on the first side;
a polymeric stiffener ring on the first side, the stiffener ring embedding the first plurality of passive devices while not covering a central portion of the first surface of the substrate; and
a semiconductor chip mounted on the central portion of the first surface of the substrate.

34. The apparatus of claim 33, wherein the polymeric stiffener ring comprises a molded a polymeric resin.

35. The apparatus of claim 33, comprising a second plurality of passive devices coupled to the central portion of the first surface of the substrate between the semiconductor chip and the stiffener ring.

36. The apparatus of claim 35, comprising a underfill layer under the semiconductor chip and over the second plurality of passive devices.

37. The apparatus of claim 33, wherein the substrate comprises a second side and a plurality of bond pads coupled to the second side.

38. The apparatus of claim 33, wherein the substrate comprises a second side and a plurality of conductor pins coupled to the second side.

39. The apparatus of claim 33, wherein the stiffener ring is rectangular.

40. The apparatus of claim 33, comprising a lid coupled to the stiffener ring and covering the semiconductor chip.

41. The apparatus of claim 33, wherein the substrate comprises a coreless substrate.
